(19) United States
(12) Patent Application Publication
(10) Pub. No.: US 2013/0135930 A1
(43) Pub. Date: May 30, 2013

(54) NONVOLATILE MEMORY APPARATUS AND METHOD FOR FABRICATING THE SAME

(71) Applicants: Sung Lae OH, Icheon-si (KR); Go Hyun LEE, Icheon-si (KR)

(72) Inventors: Sung Lae OH, Icheon-si (KR); Go Hyun LEE, Icheon-si (KR)

(73) Assignee: SK HYNIX INC., Icheon-si (KR)

(21) Appl. No.: 13/585,422

(22) Filed: Aug. 14, 2012

(30) Foreign Application Priority Data
Nov. 25, 2011 (KR) 10-2011-0124598

(51) Int. Cl. G11C 16/04; H01L 21/768

(52) U.S. Cl. 365/185.05; 438/622; 257/E21.576

(57) ABSTRACT

A nonvolatile memory apparatus includes a a memory cell array, a page buffer unit connected to bit lines of the memory cell array through a high voltage switching unit, a first interconnection configured to connect a high voltage switch of the high voltage switching unit, connected to an even bit line, to the page buffer unit, and formed at a first layer, and a second interconnection configured to connect a high voltage switch of the high voltage switching unit, connected to an odd bit line, to the page buffer unit, and formed at a second layer different from the first layer.

### CROSS-REFERENCES TO RELATED APPLICATION

The present application claims priority under 35 U.S.C. §119(a) to Korean application number 10-2011-0124598, filed on Nov. 25, 2011, in the Korean Intellectual Property Office, which is incorporated herein by reference in its entirety.

### BACKGROUND

1. Technical Field

The present invention relates to a semiconductor integrated circuit, and more particularly, to a nonvolatile memory apparatus and a method for fabricating the same.

2. Related Art

According to the recent trends, a nonvolatile memory apparatus, or particularly, a flash memory apparatus has employed an all bit-line (ABL) program method to improve program performance.

The ABL program method may simultaneously program cell strings connected to even and odd bit lines by applying a program voltage one time, compared to an even odd bit-line (EOBL) program method that programs memory cells of a cell string connected to an even bit line by applying a program voltage one time and then programs memory cells of a cell string connected to an odd bit line by additionally applying a program voltage at a different time. Because the ABL program method programs strings connected to even and odd bit lines at the same time, the ABL program method may improve program speed.

In order to support the ABL program method, a flash memory apparatus must include a page buffer unit connected to even bit lines and a page buffer unit connected to odd bit lines. Referring to FIG. 1, the configuration of FIG. 1 will be described as follows.

FIG. 1 is configuration diagram of a conventional memory apparatus, explaining a one-way ABL program method.

The nonvolatile memory apparatus 10 illustrated in FIG. 1 includes a memory cell array 11, a high voltage switching unit 13, a first page buffer unit 15, a second page buffer unit 17, even bit lines BLe and odd bit lines BLo.

The first page buffer unit 15 is connected to cell strings connected to one half of the bit lines, for example, even bit lines BLe, and the second page buffer unit 17 is connected to cell strings connected to the other half of the bit lines, for example, odd bit lines BL0. Furthermore, each of the first and second page buffer units 15 and 17 processes data for performing a program and verify operation on memory cells connected to the even bit lines BLe and the odd bit lines BLo.

The high voltage switching unit 13 is configured to apply a high voltage to a plurality of memory cells connected to each of the bit lines BLe and BLo during a program or read operation for the memory cells.

FIG. 2 is a partial configuration diagram of the nonvolatile memory apparatus illustrated in FIG. 1.

Referring to FIG. 2, the nonvolatile memory apparatus includes a drain select switch DSL, (n+1) memory cells 11-1, and a source select switch SSL, which form one string. The (n+1) memory cells 11-1 are connected in series to the drain select switch DSL, and the source select switch SSL is connected to a source terminal of the final memory cell connected in series and a common source line CSL. Furthermore, a bit line BL is extended from a drain terminal of the drain select switch DSL and connected to a unit page buffer 15-1 through a high voltage switch 13-1.

The high voltage switch 13-1 is driven by a high voltage HV provided from a high voltage generation unit (not illustrated), and the high voltage switch 13-1 has a first junction area connected to the bit line BL and a second junction area connected to the page buffer 15-1. Furthermore, a connection line between the high voltage switch 13-1 and the page buffer 15-1 may be referred to as a bit-line common line BLCM.

In the case of the nonvolatile memory apparatus to which the one-way ABL program method is applied, the first and second page buffer units 15 and 17 are arranged on one side of the memory cell array 11, as illustrated in FIG. 1. Furthermore, when the memory cell array 11 includes m bit lines, the respective m bit lines may be connected to unit page buffers of the page buffer units 15 and 17 through the high voltage switching unit 13 and m bit-line common lines BLCM.

FIG. 3 is a simple cross-sectional view of the nonvolatile memory apparatus illustrated in FIG. 2.

Referring to FIG. 3, the memory cells MC, the drain select switch DSL, and the source select switch SSL, which form one string, are formed over a substrate having a lower structure formed therein, and the drain select switch DSL and the source select switch SSL are located at both sides of the memory cells MC. Furthermore, the bit line BL is extended to the first junction area of the high voltage switch HVU from the drain select switch DSL. Furthermore, the bit-line common line BLCM is extended to the page buffer PB from the second junction area of the high voltage switch HVN.

FIG. 4 is a diagram used for explaining the layout of the nonvolatile memory apparatus illustrated in FIG. 3.

Referring to FIG. 4, bit lines BL0 to BLm and bit-line common lines BLCM0 to BLCMm are formed at both sides of the high voltage switching unit 13. The nonvolatile memory apparatus employing the one-way ABL program method requires bit-line common lines BLCM corresponding to the number m of bit lines. Furthermore, since the bit-line common lines BLCM are formed at the same layer, a width P1 of each bit-line common line BLCM and a distance P2 between the bit-line common lines BLCM are not sufficiently secured.

In order to solve such a problem, a two-way ABL program method has been adopted.

FIG. 5 is a configuration diagram of another conventional memory apparatus, explaining the two-way ABL program method.

The nonvolatile memory apparatus 30 illustrated in FIG. 5 includes a memory cell array 31, first and second high voltage switching units 33 and 37, and first and second page buffer units 35 and 39, and even and odd bit line BLe and BLo. The first high voltage switching unit 33 and the first page buffer unit 35 are formed at one side of the memory cell array 31, and the second high voltage switching unit 37 and the second page buffer unit 39 are formed at an other side of the memory cell array 31.

That is, the nonvolatile memory apparatus 30 employing the two-way ABL program method is configured in such a manner that the first high voltage switching unit 33 and the first page buffer unit 35 face the second high voltage switching unit 37 and the second page buffer unit 39 with the memory cell array 31 interposed therebetween. Furthermore, one half of the bit lines BLe and BLo, for example, even bit lines BLe are connected to the first page buffer 35 through the first high voltage switching unit 33, and the other half of the bit lines BLe and BLo, for example, odd bit lines BLo are connected to the second page buffer 39 through the second high voltage switching unit 37.

FIG. 6 is a diagram used in explaining the layout of the nonvolatile memory apparatus illustrated in FIG. 5.

The even bit lines BL0, BL2, . . . , BLm-1 are connected to a first junction area of the first high voltage switching unit 33, and even bit-line common lines BLCM0, BLCM2, . . . , BCLMm-1 are connected to a second junction area of the first high voltage switching unit 33. Furthermore, the odd bit lines BL1, BL3, . . . , BLm are connected to a first junction area of the second high voltage switching unit 37, and odd bit-line common lines BLCM1, BLCM3, . . . , BLCMm are connected to a second junction area of the second high voltage switching unit 37.

According to the above-described configuration, a width P3 of each bit-line common line BLCM and a distance P4 between the respective bit-line common lines BLCM may be sufficiently secured.

However, since the high-voltage switching units 33 and 37 and the page buffer units 35 and 39 are respectively arranged at both sides of the memory cell array 31 so as to face each other, the chip area inevitably increases. Furthermore, when a high-speed operation is required, efficiency may be degraded.

### SUMMARY

In one embodiment of the present invention, a nonvolatile memory apparatus includes: a memory cell array; a page buffer unit connected to bit lines of the memory cell array through a high voltage switching unit; a first interconnection configured to connect a high voltage switch of the high voltage switching unit, connected to an even bit line, to the page buffer unit, and formed at a first layer; and a second interconnection configured to connect a high voltage switch of the high voltage switching unit, connected to an odd bit line, to the page buffer unit, and formed at a second layer different from the first layer.

In another embodiment of the present invention, a nonvolatile memory apparatus includes: a memory cell array comprising a plurality of memory cells connected between a plurality of bit lines and word lines; a page buffer unit arranged at one side of the memory cell array; a high voltage switching unit comprising a plurality of high voltage switches having one side connected to the respective bit lines and an other side connected to the page buffer unit; a first interconnection configured to connect a high voltage switch, connected to each bit line of a first bit line group comprising bit lines which are not adjacent to each other among the bit lines, to the page buffer unit, and formed at a first layer; and a second interconnection configured to connect a high voltage switch, connected to each bit line of a second bit line group comprising the other bit lines excluding the first bit line group among the bit lines, to the page buffer unit, and formed at a second layer different from the first layer.

In another embodiment of the present invention, a method for fabricating a nonvolatile memory apparatus includes the steps of: providing a semiconductor substrate defining a first region where a memory cell array is formed, a high voltage switching region where a first high voltage switching unit and a second high voltage switching unit are formed, and a peripheral region where a page buffer are formed; forming a first interconnection at a first layer such that the first interconnection is connected from a second junction area of the first high voltage switching unit to the page buffer; and forming a second interconnection at a second layer different from the first layer such that the second interconnection is connected from a second junction area of the second high voltage switching unit to the page buffer.

### BRIEF DESCRIPTION OF THE DRAWINGS

Features, aspects, and embodiments are described in conjunction with the attached drawings, in which:

FIG. 1 is configuration diagram of a conventional memory apparatus;

FIG. 2 is a partial configuration diagram of the nonvolatile memory apparatus illustrated in FIG. 1;

FIG. 3 is a simple cross-sectional view of the nonvolatile memory apparatus illustrated in FIG. 2;

FIG. 4 is a diagram used for explaining the layout of the nonvolatile memory apparatus illustrated in FIG. 3;

FIG. 5 is a configuration diagram of another conventional memory apparatus;

FIG. 6 is a diagram used for explaining the layout of the nonvolatile memory apparatus illustrated in FIG. 5;

FIG. 7 is a configuration diagram of a nonvolatile memory apparatus according to one embodiment of the present invention;

FIGS. 8 and 9 are cross-sectional views of the nonvolatile memory apparatus illustrated in FIG. 7; and

FIG. 10 is a diagram explaining the layout of the nonvolatile memory apparatus illustrated in FIG. 7.

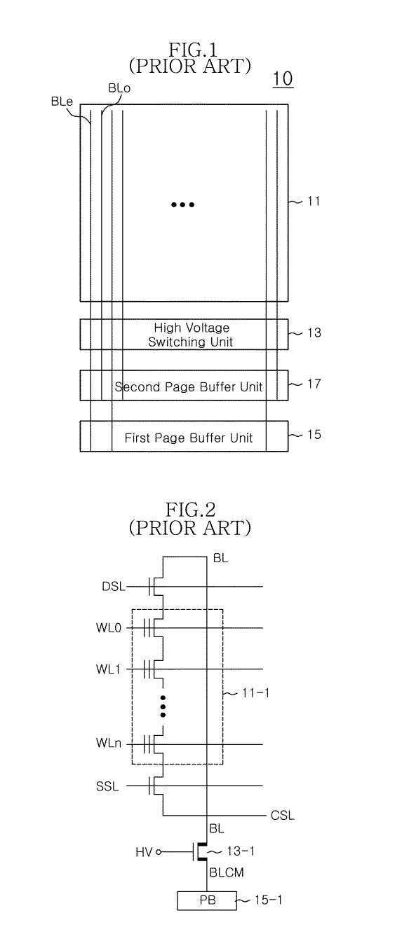

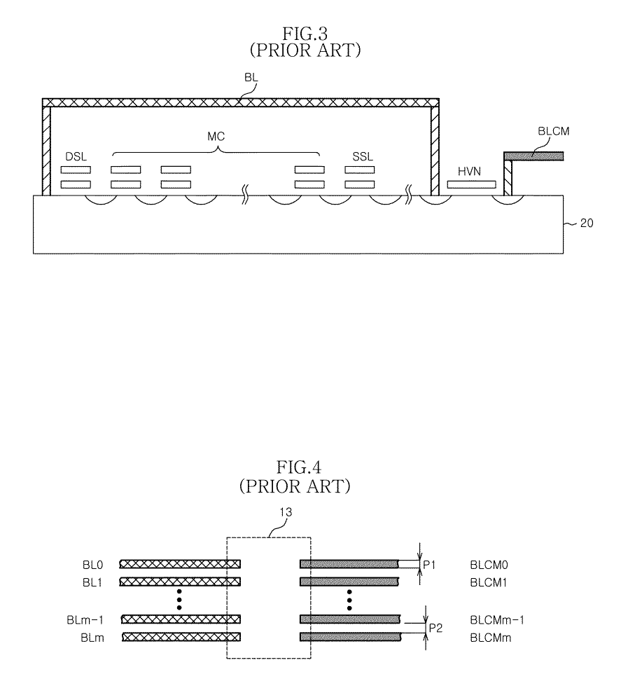

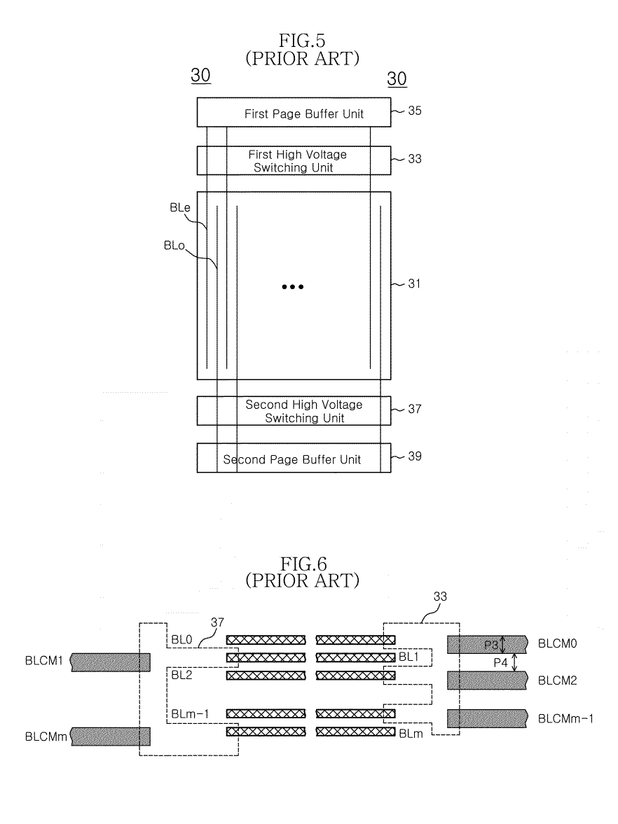

### DETAILED DESCRIPTION

Hereinafter, a nonvolatile memory apparatus and a method for fabricating the same according to the present invention will be described below with reference to the accompanying drawings through example embodiments.

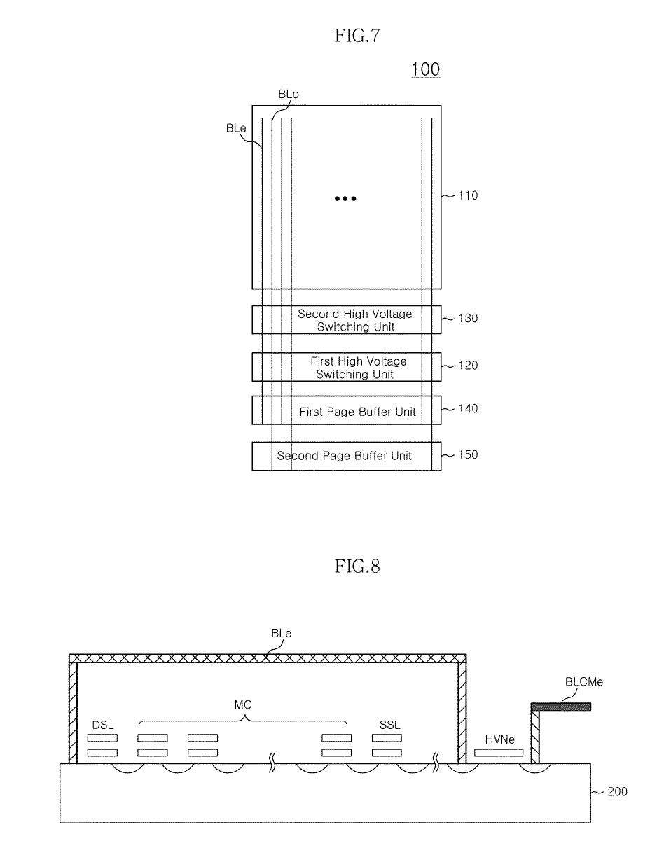

FIG. 7 is a configuration diagram of a nonvolatile memory apparatus according to one embodiment of the present invention.

Referring to FIG. 7, the nonvolatile memory apparatus 100 according to an embodiment of the present invention includes a memory cell array 110, a high voltage switching unit 120 and 130, and a page buffer unit 140 and 150. Although, the high voltage switching unit 120 and 130 is depicted as two separate boxes in FIG. 7, the high voltage switching unit 120 and 130 may be realized as one switching unit, or may be separated into two switching units. Similarly, the page buffer unit 140 and 150 is depicted as two separate boxes in FIG. 7, but the page buffer unit 140 and 150 may be realized as one page buffer unit or separated into two page buffer units. The high voltage switching unit 120 and 130 may be arranged at a first side of the memory cell array 110 so as to be connected to bit lines BL, and the page buffer unit 140 and 150 is also arranged at the first side of the memory cell array 110 so as to be connected to the high voltage switching unit 120 and 130 through bit-line common lines BLCM.

In this embodiment of the present invention, the high voltage switching unit 120 and 130 may be divided into a first high voltage switching unit 120 connected to even bit lines BLe and a second high voltage switching unit 130 connected to odd bit line BLo, but is not limited thereto. Furthermore, the page buffer unit 140 and 150 may be divided into a first page buffer unit 140 connected to the first high voltage switching unit 120 through even bit-line common lines BLCMe and a second page buffer unit 150 connected to the second high voltage switching unit 130 through odd bit-line common lines BLCMo.

More specifically, the first high voltage switching unit 120 may be connected to a group of bit lines BL which are not adjacent to each other among bit lines BL extended from the memory cell array 110, for example, the even bit lines BLe, and provides a high voltage to memory cells connected to the corresponding bit lines BLe during a program or read operation. Similarly, the second high voltage switching unit 130 is connected to a group of the other bit lines which are not connected to the first high voltage switching unit 120 among the bit lines BL extended from the memory cell array 110, for example, the odd bit lines BLo, and provides a high voltage to memory cells connected to the corresponding bit lines BLo during a program or read operation.

The first page buffer unit 140 may be connected to the first high voltage switching unit 120, and the first page buffer unit 140 may process data for performing a program and verify operation. Similarly, the second page buffer unit 150 is connected to the second high voltage switching unit 130, and the second page buffer unit 150 may process data for performing a program and verify operation.

That is, the nonvolatile memory apparatus 100 illustrated in FIG. 7 supports the one-way ABL program method, and each of the bit lines is connected to a unit page buffer through a high voltage switch.

In this case, in order to sufficiently secure a width of bit-line common lines BLCM connecting the high voltage switches and the page buffers, the present invention includes a method in which the bit-line common lines BLCM are divided into two groups, and the bit-line common lines BLCM of each group are arranged at a different layer.

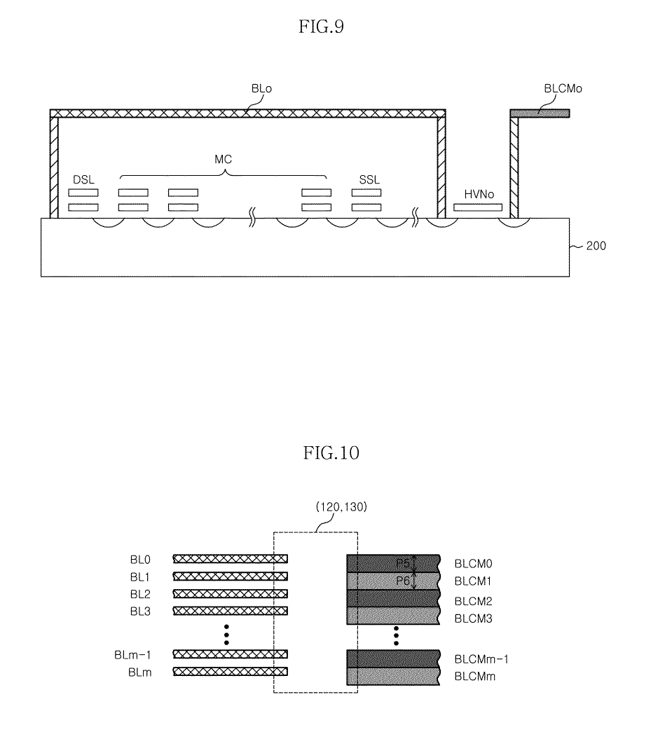

FIGS. 8 and 9 are cross-sectional views of the nonvolatile memory apparatus illustrated in FIG. 7.

Referring to FIGS. 8 and 9, memory cells MC, a drain select switch DSL, and a source select switch SSL, which form one string, are formed over a substrate 200 having a lower structure formed therein. The drain select switch DSL and the source select switch SSL are formed at both sides of the memory cells MC, respectively. Furthermore, high voltage switches HVNe and HVNo are formed in a high voltage switching region of the substrate 200. Although not illustrated, page buffers may be formed in a peripheral region over the substrate 200.

Referring to FIG. 8, an even bit line BLe is extended from the drain select switch DSL to a first junction area of the high voltage switch HVNe which may be formed in the first high voltage switching unit 120. Furthermore, an even bit-line common line BLCMe is extended from a second junction area of the high voltage switch HVNe and connected to a page buffer PB.

Similarly, referring to FIG. 9, an odd bit line BLo is extended from the drain select switch DSL to a first junction area of the high voltage switch HVNo which may be formed in the second high voltage switching unit 130. Furthermore, an odd bit-line common line BLCMo is extended from a second junction area of the high voltage switch HVNo and connected to a page buffer PB. Thus, the high voltage switching unit 120 and 130 may comprise a plurality of high voltage switches HVNe and HVNo having one side connected to respective bit lines and an other side connected to the page buffer unit 140 and 150. Accordingly, via the high voltage switches HVNe and HVNo, the high voltage switching unit 120 and 130 may comprise an interconnection formed from the second junction area to the page buffer 140 and 150. Further, via the high voltage switches HVNe and HVNo, the high voltage switching unit 120 and 130 may comprise an interconnection formed from the first junction area to the memory cell array 110.

The even bit-line common line BLCMe may be formed at a different layer, layer or height than the odd bit-line common line BLCMo.

For example, the even bit-line common line BLCMe may be formed at the same layer as or a lower layer than the bit line BLe, as illustrated in FIG. 8, and the odd bit-line common line BLCMo may be formed at a lower layer or further lower layer than the bit line BLo, as illustrated in FIG. 9.

On the other hand, the odd bit-line common line BLCMo may be formed at the same layer as or a lower layer than the bit line BLo, and the even bit-line common line BLCMe may be formed at a lower layer or further lower layer than the bit line BLe.

Here, the layer at which the bit line BL formed may be referred to as a second interconnection layer M1 (not pictured), a lower layer of the bit line BL may be referred to as a first interconnection layer M0, and may include a lower layer than the first interconnection layer M0.

That is, regardless of which layers the bit-line common lines are arranged, the even bit-line common line BLCMe and the odd bit-line common line BLCMo are not formed at a same layer. Accordingly, as the even bit-line common line BLCMe and the odd bit-line common line BLCMo are formed at different layers, the width of the bit-line common lines BLCMe and BLCMo and the distance between the respective bit-line common lines BLCMe and BLCMo may be sufficiently secured.

FIG. 10 is a diagram explaining the layout of the nonvolatile memory apparatus illustrated in FIG. 7.

In order to implement the ABL program method, or particularly, the one-way ABL program method, an interconnection comprising the respective bit lines BL0 to BLm which may be connected to the high voltage switching unit 120 and 130 which are formed at one side of the memory cell array 110. The high voltage switching unit 120 and 130 may be connected to the page buffer unit 140 and 150 and are arranged on the same side of the memory cell array 110 as the high voltage switching unit 120 and 130. The high voltage switching unit 120 and 130 and the page buffer units 140 and 150 may be connected through the bit-line common lines BLCM0 to BLCMm.

At this time, referring to FIGS. 8 and 9, the even bit-line common lines BLCMe and the odd bit-line common lines BLCMo may be arranged at different layers. Thus, a first interconnection may include the even bit-line common lines BLCMe and may comprise at least one high voltage switch of the high voltage switching unit 120 and 130 connected to an even bit line BLe and the page buffer unit 140 and 150, and the first interconnection may be formed at a first layer. A second interconnection may include the odd bit-line common lines BLCMo and may comprise at least one high voltage switch of the high voltage switching unit 120 and 130 connected to an odd bit line BLo and the page buffer unit 140 and 150, and the second interconnection may be formed at a second layer. Further, the first interconnection may comprise the high voltage switching unit 120 and 130 connected to each bit line of a first bit line group, where the first bit line group may be comprised of a group of bit lines that are not adjacent to each other, for example, even bit lines BLe. The second interconnection may comprise the high voltage switching unit 120 and 130 connected to each bit line of a second bit line group, where the second bit line group may be comprised of a group of bit lines that are not adjacent to each other, for example, odd bit lines BLo. Still further, in one embodiment, the high voltage switches of the first high voltage switching unit 120 may be connected to even bit lines, and the high voltage switches of the second high voltage switching unit 130 may be connected to odd bit lines. In another embodiment, the high voltage switches of the first high voltage switching unit 120 may be connected to odd bit lines, and the high voltage switches of the second high voltage switching unit 130 may be connected to even bit lines. Further, the first page buffer unit 140 may include page buffers connected with the high voltage switches of the first high voltage switching unit 120, and the second page buffer unit 150 may include page buffers connected with the high voltage switches of the second high voltage switching unit 130, as well as vice-versa.

Therefore, the width P5 of the bit-line common lines BLCM0 to BLCMm and the distance P6 between the respective bit-line common lines BLCM0 to BLCMm may be sufficiently secured.

Furthermore, since the high voltage switching unit 120 and 130 and the page buffer unit 140 and 150 are arranged on one side of the memory cell array 110, it is possible to secure the same design rule as in the two-way ABL program method, without increasing a chip size.

In order to fabricate such a nonvolatile memory apparatus, first, the semiconductor substrate 200 having a lower structure formed therein is provided. The semiconductor substrate 200 may define a memory cell region, a high voltage switching region, and a peripheral region.

Furthermore, the drain select switch DSL, the memory cell string MC, and the source select switch SSL are formed in the memory cell region of the semiconductor substrate 200, and the high voltage switches HVNe and HVNo are formed in the high voltage switching region. Furthermore, unit page buffers are formed in the peripheral region.

For example, when the bit-line common lines BLCMe and BLCMo are arranged as illustrated in FIGS. 8 and 9, the even bit-line common line BLCMe may be formed at the first interconnection layer M0, and the even bit-line common line BLCMe may be connected to the second junction area of the even high voltage switch HVNe. The odd bit-line common line BLCMo may be formed at the second interconnection layer M1, and the odd bit-line common line BLCMo may be connected to the second junction area of the odd high voltage switch HVNo. Thus, the first interconnection may be connected from the second junction area of the first high voltage switching unit 120 to the page buffer 140 and 150, for example the first page buffer 140. The second interconnection may be formed at a second layer, which may be different from the first layer. The second interconnection may be connected from the second junction area of the second high voltage switch 130 to the page buffer 140 and 150, for example the second page buffer 150.

The even bit line BLe connected to the first junction area of the even high voltage switch HVNe and the odd bit line BLo connected to the first junction area of the odd high voltage switch HVNo may be formed at the second interconnection layer M1. The odd bit-line common line BLCMo may be formed so as to be connected to the second junction area of the odd high voltage switch HVNo.

As a result, since the even bit-line common line BLCMe and the odd bit-line common line BLCMo are formed at different layers M0 and M1, it is possible to sufficiently secure the width P5 of the bit-line common lines BLCM and the distance P6 between the bit-line common lines BLCM.

In this embodiment of the present invention, it has been described that the even bit-line common line BLCMe is formed at the first interconnection layer M0 and the odd bit-line common line BLCMo is formed at the second interconnection layer M1, but the present invention is not limited thereto. That is, any other structures may be adopted as long as the even bit-line common line BLCMe and the odd bit-line common line BLCMo are formed at different layers.

While certain embodiments have been described above, it will be understood to those skilled in the art that the embodiments described are by way of example only. Accordingly, the apparatus and method described herein should not be limited based on the described embodiments. Rather, the apparatus and method described herein should only be limited in light of the claims that follow when taken in conjunction with the above description and accompanying drawings.

What is claimed is:

1. A nonvolatile memory apparatus comprising:
a memory cell array;
a page buffer unit connected to bit lines of the memory cell array through a high voltage switching unit;
a first interconnection configured to connect a high voltage switch of the high voltage switching unit, connected to an even bit line, to the page buffer unit, and formed at a first layer; and
a second interconnection configured to connect a high voltage switch of the high voltage switching unit, connected to an odd bit line, to the page buffer unit, and formed at a second layer different from the first layer.

2. The nonvolatile memory apparatus according to claim 1, wherein the high voltage switching unit and the page buffer unit are arranged at one side of the memory cell array.

3. The nonvolatile memory apparatus according to claim 1, wherein the nonvolatile memory apparatus has an all bit-line (ABL) structure.

4. The nonvolatile memory apparatus according to claim 1, wherein the first layer comprises a layer having the bit lines formed therein or a lower layer of the layer.

5. The nonvolatile memory apparatus according to claim 1, wherein the second layer comprises a layer having the bit lines formed therein or a lower layer of the layer.

6. A nonvolatile memory apparatus comprising:
a memory cell array comprising a plurality of memory cells connected between a plurality of bit lines and word lines;
a page buffer unit arranged at one side of the memory cell array;
a high voltage switching unit comprising a plurality of high voltage switches having one side connected to the respective bit lines and an other side connected to the page buffer unit;
is a first interconnection configured to connect a high voltage switch, connected to each bit line of a first bit line group comprising bit lines which are not adjacent to each other among the bit lines, to the page buffer unit, and formed at a first layer; and
a second interconnection configured to connect a high voltage switch, connected to each bit line of a second bit line group comprising the other bit lines excluding the first bit line group among the bit lines, to the page buffer unit, and formed at a second layer different from the first layer.

7. The nonvolatile memory apparatus according to claim 6, wherein the first layer comprises a layer at which the bit lines are formed.

8. The nonvolatile memory apparatus according to claim 6, wherein the first layer comprises a layer lower than a layer at which the bit lines are formed.

9. The nonvolatile memory apparatus according to claim 6, wherein the high voltage switching unit comprises:
a first high voltage switching unit comprising high voltage switches connected to even bit lines; and
a second high voltage switching unit comprising high voltage switches connected to odd bit lines.

10. The nonvolatile memory apparatus according to claim 9, wherein the page buffer unit comprises;
a first page buffer unit comprises page buffers connected to the high voltage switches included in the first high voltage switching unit; and
a second page buffer unit comprises page buffers connected to the high voltage switches included in the second high voltage switching unit.

11. A method for fabricating a nonvolatile memory apparatus, comprising the steps of:
providing a semiconductor substrate defining a first region where a memory cell array is formed, a high voltage switching region where a first high voltage switching unit and a second high voltage switching unit are formed, and a peripheral region where a page buffer are formed;
forming a first interconnection at a first layer such that the first interconnection is connected from a second junction area of the first high voltage switching unit to the page buffer; and
forming a second interconnection at a second layer different from the first layer such that the second interconnection is connected from a second junction area of the second high voltage switching unit to the page buffer.

12. The method according to claim 11, further comprising the step of forming bit lines at a third layer higher than the first layer such that the bit lines are extended to the memory cell array from a first junction area of the first high voltage switching unit and a first junction area of the second high voltage switching unit.

13. The method according to claim 11, wherein the second layer is the same layer as the third layer.

14. The method according to claim 11, wherein the second layer is an upper layer than the first layer and a lower layer than the third layer.

15. The method according to claim 11, wherein the first high voltage switching unit comprises high voltage switches connected to even bit lines among the bit lines.

16. The method according to claim 11, wherein the second high voltage switching unit comprises high voltage switches connected to odd bit lines among the bit lines.
